(19) United States
(12) Patent Application Publication
(10) Pub. No.: US 2014/0036198 A1
(43) Pub. Date: Feb. 6, 2014

(54) SUBSTRATE MODULE, ELECTRONIC APPARATUS, AND MANUFACTURING METHOD FOR ELECTRONIC APPARATUS

(71) Applicant: FUJITSU LIMITED, Kawasaki-shi (JP)

(72) Inventor: Masayuki KITAJIMA, Yokohama (JP)

(21) Appl. No.: 13/930,888

(22) Filed: Jun. 28, 2013

(30) Foreign Application Priority Data
Aug. 6, 2012 (JP) 2012-174078

(51) Int. Cl. H05K 7/06; G02F 1/1333

(52) U.S. Cl. CPC H05K 7/06; G02F 1/133308
USPC 349/58; 264/272.11; 174/521

(57) ABSTRACT

A substrate module includes: a substrate on which an electronic component is mounted; and a sealing resin that seals the electronic component, and has an opening, the opening being open along an extending direction of the substrate.

### CROSS-REFERENCE TO RELATED APPLICATION

This application is based upon and claims the benefit of priority of the prior Japanese Patent Application No. 2012-174078, filed on Aug. 6, 2012, the entire contents of which are incorporated herein by reference.

### FIELD

The embodiments discussed herein are related to a substrate module, an electronic apparatus, and a manufacturing method for an electronic apparatus.

### BACKGROUND

In related art, there are substrate modules including a substrate, and a sealing resin that seals electronic components mounted on this substrate.

As related art, there are Japanese Laid-open Patent Publication No. 8-102583, Japanese Laid-open Patent Publication No. 9-162229, Japanese Laid-open Patent Publication No. 4-97550, Japanese Laid-open Patent Publication No. 11-45961, and Japanese Laid-open Patent Publication No. 6-252534.

In some electronic apparatuses including a substrate module of this kind and a housing, the housing is formed integrally with the substrate module in a state in which the substrate module is received in a forming mold. In some cases, the housing has a coating portion that is formed opposite to the substrate across the sealing resin. However, in cases where the sealing resin and the coating portion are formed in a stacked manner in this way, there is a fear that the coating portion may detach from the sealing resin owing to impact, vibration, or the like.

Accordingly, as an aspect of the embodiments, it is an object of the embodiments to reduce detachment of the coating portion formed in the housing from the sealing resin.

### SUMMARY

According to an aspect of the invention, a substrate module includes: a substrate on which an electronic component is mounted; and a sealing resin that seals the electronic component, and has an opening, the opening being open along an extending direction of the substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view taken along the transverse direction of an electronic apparatus according to a first embodiment;

FIG. 2 is a sectional view taken along the longitudinal direction of the electronic apparatus illustrated as FIG. 1;

FIG. 3 is a plan view of sealing resin illustrated as FIG. 1;

FIG. 4 is an explanatory drawing for explaining a manufacturing method for the electronic apparatus illustrated as FIG. 1;

FIG. 5 is a plan view illustrating a first modification of the sealing resin illustrated as FIG. 1;

FIG. 6 is a plan view illustrating a second modification of the sealing resin illustrated as FIG. 1;

FIG. 7 is a plan view illustrating a third modification of the sealing resin illustrated as FIG. 1;

FIG. 8 is a sectional view taken along the longitudinal direction of an electronic apparatus according to a second embodiment;

FIG. 9 is a plan view of sealing resin illustrated as FIG. 8;

FIG. 10 is a plan view illustrating a first modification of the sealing resin illustrated as FIG. 8;

FIG. 11 is a plan view illustrating a second modification of the sealing resin illustrated as FIG. 8;

FIG. 12 is a sectional view taken along the longitudinal direction of an electronic apparatus according to a third embodiment;

FIG. 13 is a plan view of sealing resin illustrated as FIG. 12;

FIG. 14 is a sectional view taken along the longitudinal direction of an electronic apparatus according to a fourth embodiment;

FIG. 15 is a plan view of sealing resin illustrated as FIG. 14;

FIG. 16 is a plan view illustrating a modification of the sealing resin illustrated as FIG. 14; and

FIG. 17 is a sectional view taken along the longitudinal direction of an electronic apparatus according to a reference example.

### DESCRIPTION OF EMBODIMENTS

### First Embodiment

First, a first embodiment will be described.

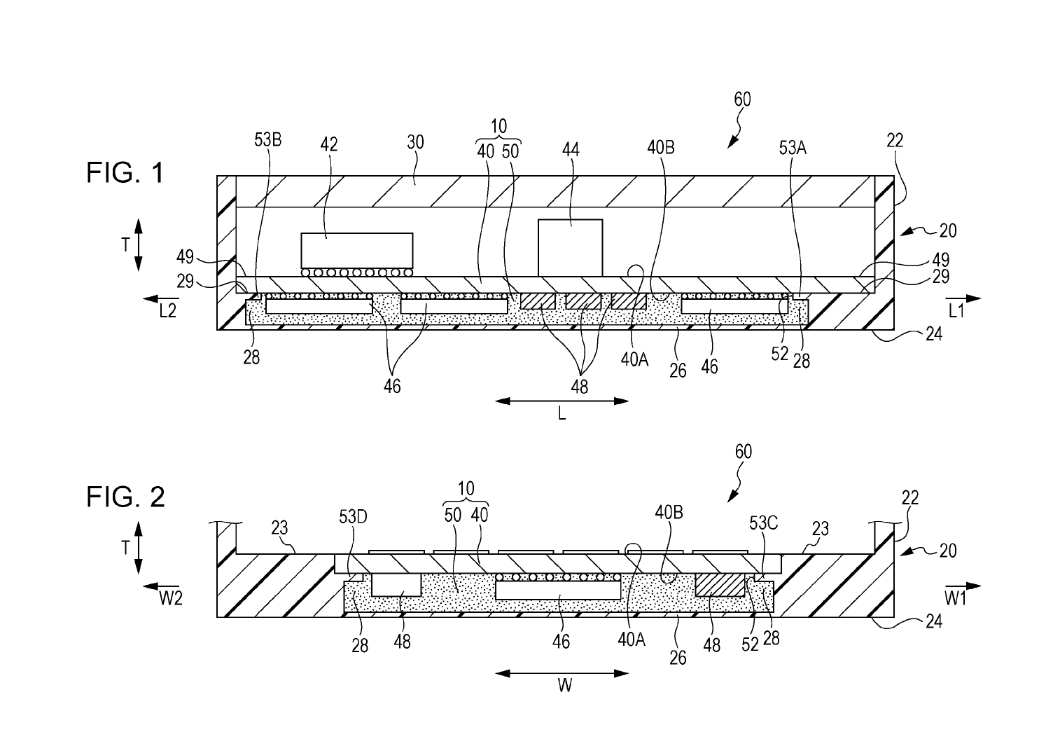

As illustrated as FIG. 1, an electronic apparatus 60 according to the first embodiment includes a substrate module 10, a housing 20, and a liquid crystal display 30.

The substrate module 10 has a substrate 40 and a sealing resin 50. The substrate 40 is formed in a rectangular shape (oblong shape) in plan view. An electronic component 42 such as an integrated circuit (IC), a connector 44, and the like are mounted on one mounting surface 40A of the substrate 40. An electronic component 46 such as an IC, resistance elements 48, and the like are mounted on another mounting surface 40B of the substrate 40.

The sealing resin 50 is formed of epoxy resin, for example. The sealing resin is formed by resin molding and integrated with the substrate 40. The sealing resin 50 is formed in a plate-like shape that covers the other mounting surface 40B of the substrate 40. The sealing resin 50 seals the electronic component 46, the resistance elements 48, and the like mounted on the mounting surface 40B.

The sealing resin 50 is formed in a rectangular shape (oblong shape) in plan view. The sealing resin 50 is formed so as to be smaller than the substrate 40 in the longitudinal direction (direction L). End portions 49 on both longitudinal sides of the substrate 40 are projected with respect to the sealing resin 50. As illustrated as FIG. 2, in the transverse direction (direction W) of the substrate 40, the sealing resin 50 is formed in substantially the same size as the substrate 40.

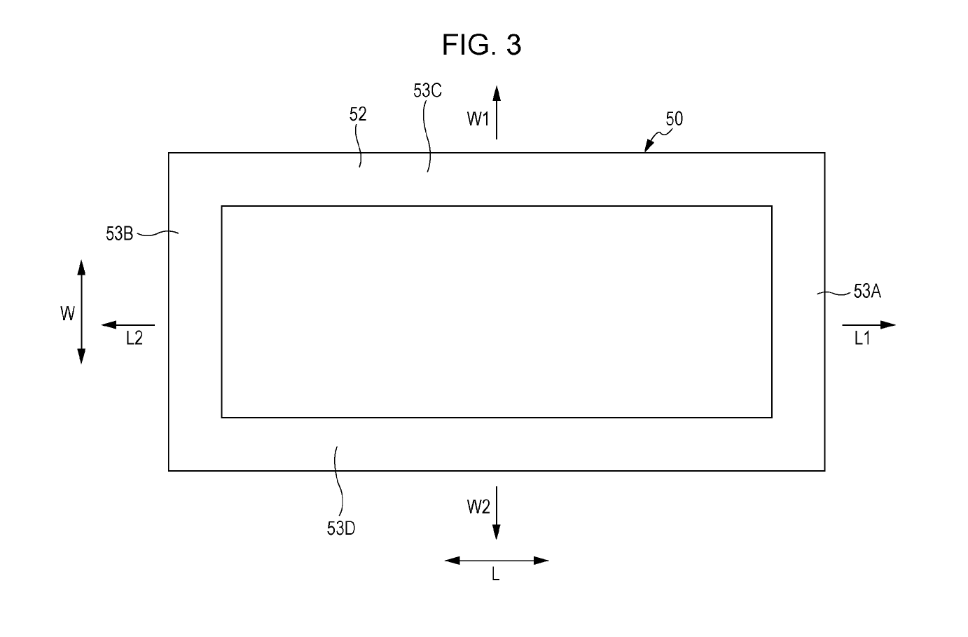

As illustrated as FIGS. 1 and 2, an opening 52 is formed in a surface portion on the substrate 40 side of the sealing resin 50. The opening 52 is formed as a cutout that is recessed toward the center of the sealing resin 50 in plan view. The opening 52 is formed, for example, at the time of molding of the sealing resin 50. As illustrated as FIG. 3, the opening 52 is formed in an annular shape along the peripheral edge portion of the sealing resin. More specifically, the opening 52 has a plurality of cutout portions 53A to 53D.

That is, the cutout portion 53A and the cutout portion 53B extend in the transverse direction (direction W) of the sealing resin 50, and the cutout portion 53C and the cutout portion 53D extend in the longitudinal direction (direction L) of the sealing resin 50. As illustrated as FIG. 1, the cutout portion 53A is open on one side (L1 side) in the longitudinal direction of the sealing resin 50, and the cutout portion 53B is open on the other side (L2 side) in the longitudinal direction of the sealing resin 50. In addition, as illustrated as FIG. 2, the cutout portion 53C is open on one side (W1 side) in the transverse direction of the sealing resin 50, and the cutout portion 53D is open on the other side (W2 side) in the transverse direction of the sealing resin 50. Each of the longitudinal and transverse directions of the sealing resin 50 is an example of a direction along the extending direction of the substrate 40.

The housing 20 is formed of a resin such as a mixed resin of polycarbonate (PC) and acrylonitrile butadiene styrene (ABS), or polypropylene (PP), for example. The housing 20 is formed by molding (integral molding by injection molding). As illustrated as FIG. 1, the housing 20 has a peripheral wall portion 22 and a back portion 24.

The peripheral wall portion 22 is formed in an annular shape along the peripheral edge portion of the back portion 24. The substrate 40 and the liquid crystal display 30 mentioned above are accommodated inside the peripheral wall portion 22. The substrate 40 is arranged on the proximal end side of the peripheral wall portion 22, and the liquid crystal display 30 is assembled onto the distal end portion of the peripheral wall portion 22.

The back portion 24 is provided opposite to the liquid crystal display 30 with respect to the substrate 40. The back portion 24 is integrated with the substrate 40 and the sealing resin 50. The back portion 24 has a coating portion 26 that is formed opposite to the substrate 40 across the sealing resin 50. The coating portion 26 covers the entirety of the sealing resin 50 from the side opposite to the substrate 40. In order to reduce the thickness of the electronic apparatus 60, the coating portion 26 is formed so as to be thinner than each of the substrate 40 and the sealing resin 50.

The back portion 24 of the housing 20 is provided with an inflow portion 28 that has flown into the opening 52 at the time of molding. End portions 29 on both longitudinal sides of the back portion 24 are overlapped with the end portions 49 on both longitudinal sides of the substrate 40. The coating portion 26, the inflow portion 28, and the end portions 29 are formed integrally with the back portion 24. As illustrated as FIG. 2, in the housing 20, a support portion 23 that supports the substrate 40 is formed between the substrate 40 and the peripheral wall portion 22 in the transverse width direction (direction W) of the housing 20.

Next, a manufacturing method for the electronic apparatus 60 mentioned above will be described.

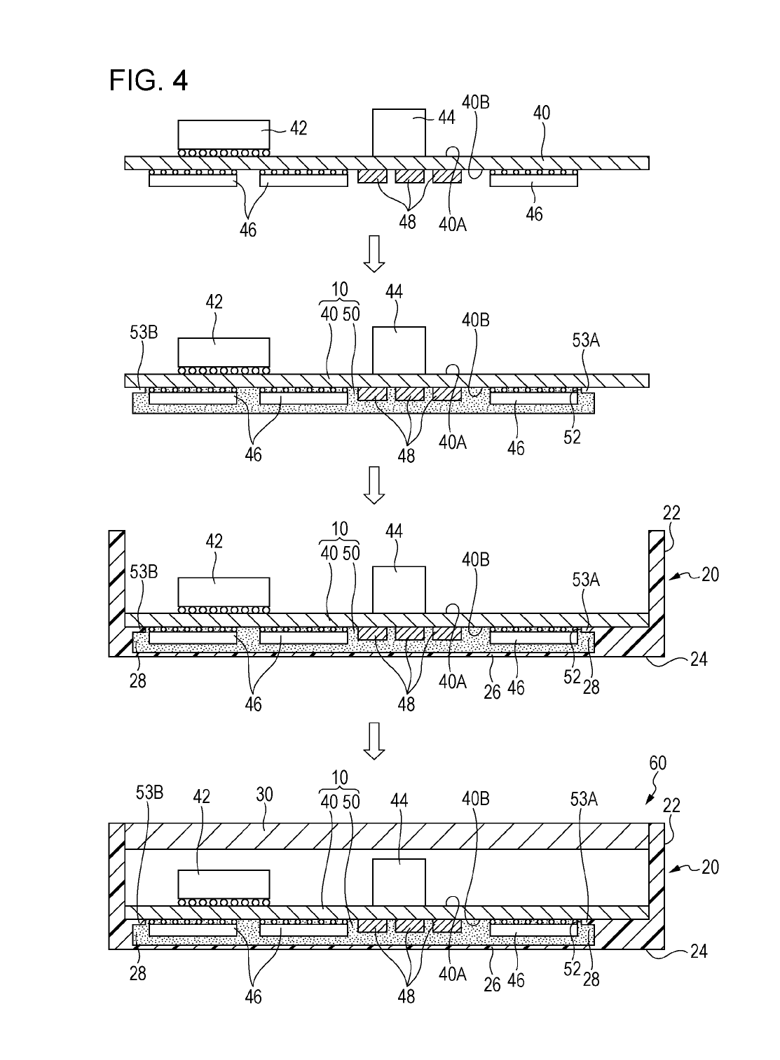

As illustrated as FIG. 4, first, the electronic component 46 and the like are mounted (installed) on the substrate 40. Subsequently, the sealing resin 50 is formed by resin molding on the mounting surface 40B side of the substrate 40, and the electronic component 46 and the like mounted on the mounting surface 40B is sealed by the sealing resin 50. Moreover, the opening 52 is formed in the sealing resin 50 by a convex portion formed in a mold, a segmented mold, or the like (sealing resin forming step).

Next, the substrate 40 integrated with the sealing resin 50 is accommodated into the mold. Molten resin is poured into this mold, and as this molten resin cools and solidifies, the housing 20 made of resin is formed. When the housing 20 is formed by molding in this way, the coating portion 26 is formed opposite to the substrate 40 across the sealing resin 50, and a part of the molten resin flows into the opening 52, forming the inflow portion 28 (housing forming step).

Then, the liquid crystal display 30 is assembled onto the distal end portion of the peripheral wall portion 22 of the housing 20. The electronic apparatus 60 is manufactured in the above-mentioned manner.

Next, operation and effects of the first embodiment will be described.

According to the first embodiment, as illustrated as FIGS. 1 and 2, the opening 52 that is open in the longitudinal direction and transverse direction (direction L and direction W) of the sealing resin 50 is formed in the sealing resin 50 that seals the electronic component 46 and the like. The inflow portion 28 is made to flow into the opening 50. Therefore, because the inflow portion 28 and the coating portion 26 go round both sides in the thickness direction (direction T) of the sealing resin 50, detachment of the coating portion 26 from the sealing resin 50 may be reduced even in a case where, for example, bending stress is exerted on the housing 20, or impact caused by dropping is applied to the housing 20.

That is, it is possible to reduce bending deformation of the entire back portion 24 including the coating portion 26 so as to be convex to the side opposite to the liquid crystal display 30. In particular, even when the housing 20 having the coating portion 26 is made of, for example, polypropylene that exhibits low adhesion, detachment of the coating portion 26 from the sealing resin 50 may be reduced. This makes it possible to ensure the reliability of an electrical circuit and the like formed on the substrate 40.

The opening 52 is formed in an annular shape along the peripheral edge portion of the sealing resin 50 (see FIG. 3). Therefore, it is possible to reduce detachment of the coating portion 26 from the sealing resin 50 over the entire periphery of the sealing resin 50.

The cutout portions 53A and 53B of the opening 52 are separated from each other in the longitudinal direction of the sealing resin 50, and the cutout portions 53C and 53D of the opening 52 are separated from each other in the transverse direction of the sealing resin 50. Therefore, the coating portion 26 is restrained in the longitudinal direction and the transverse direction by the inflow portion 28 that has flown into each of the cutout portions 53A to 53D, which also makes it possible to reduce detachment of the coating portion 26 from the sealing resin 50.

The opening 52 is formed as a cutout that is open in the longitudinal direction and transverse direction of the sealing resin 50. Therefore, the opening 52 may be formed easily at the time of resin molding of the sealing resin 50, for example.

Next, modifications of the first embodiment will be described.

While in the first embodiment the sealing resin 50 is formed in a rectangular shape (oblong shape) in plan view, the sealing resin 50 may be formed in a polygonal shape such as a convex polygon or a concave polygon. Moreover, the opening 52 may be formed in an annular shape along the peripheral edge portion of the sealing resin 50, in conformity with the outer shape of the sealing resin 50 formed in the polygonal shape in this way.

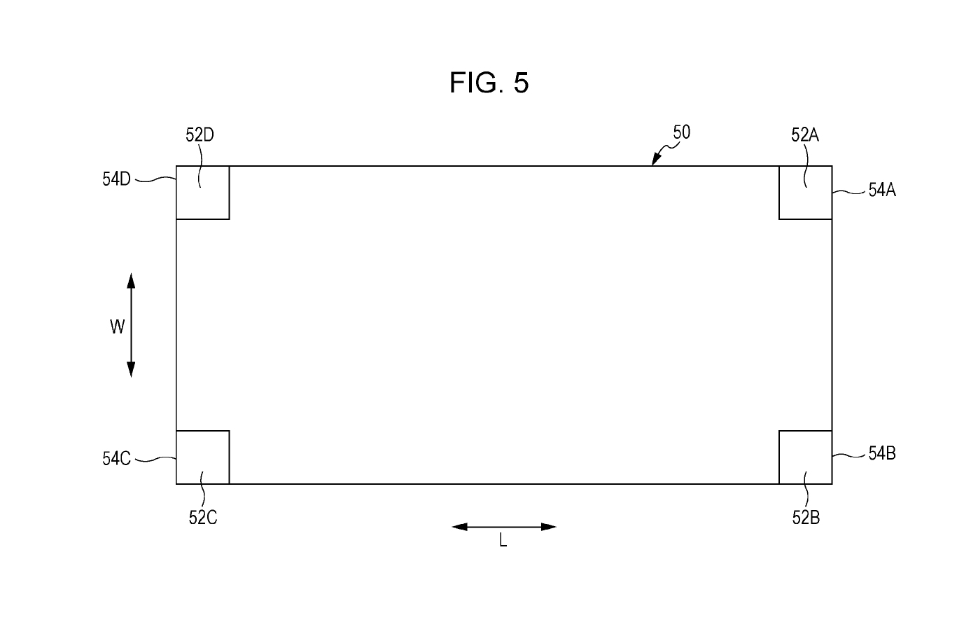

While in the first embodiment the sealing resin 50 has one opening 52 that is formed in an annular shape along the peripheral edge portion of the sealing resin 50, the sealing resin 50 may have a plurality of openings 52A to 52D as illustrated as FIG. 5. In this case, the plurality of openings 52A to 52D may be formed at corner portions 54A to 54D, respectively, of the sealing resin 50. When the openings 52A to 52D are formed in this way, it is possible to reduce detachment of the above-mentioned coating portion 26 (see FIG. 1) from the sealing resin 50 at the corner portions 54A to 54D of the sealing resin 50 where stress tends to concentrate.

The plurality of openings 52A to 52D may be formed at the corner portions of the sealing resin 50 after the sealing resin 50 is formed in a polygonal shape such as a convex polygon or a concave polygon in plan view.

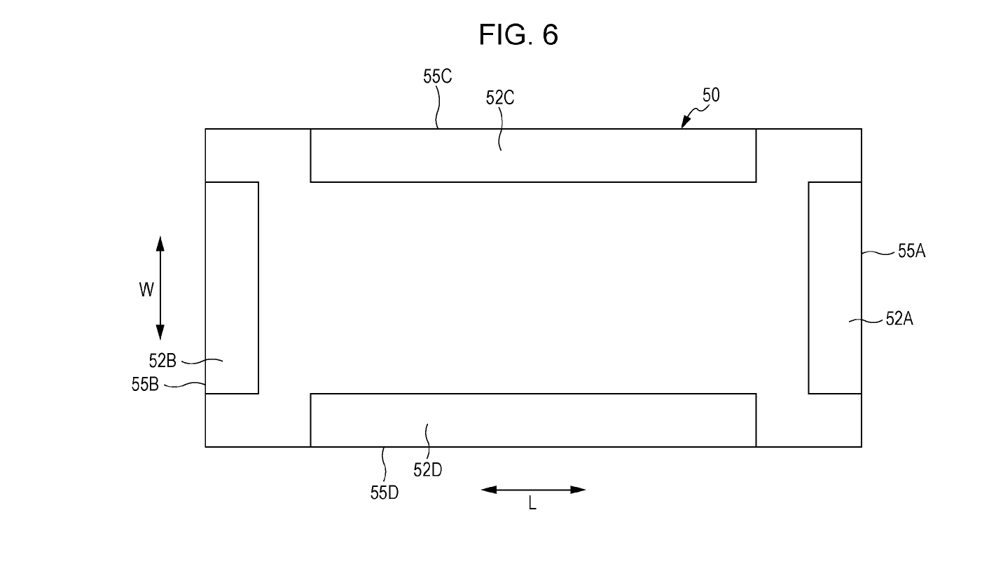

In the first embodiment, as illustrated as FIG. 6, the plurality of openings 52A to 52D may be formed along the side portions of the sealing resin 50. That is, the openings 52A and 52B are formed along transverse side portions 55A and 55B, respectively, of the sealing resin 50, and the openings 52C and 52D are formed along longitudinal side portions 55C and 55D, respectively, of the sealing resin 50. Each of the transverse side portions 55A and 55B and the longitudinal side portions 55C and 55D is an example of a side portion. When the openings 52A to 52D are formed in this way, it is possible to reduce detachment of the above-mentioned coating portion 26 (see FIG. 1) from the sealing resin 50 in the side portions of the sealing resin 50.

The plurality of openings 52A to 52D may be formed along the side portions of the sealing resin 50 after the sealing resin 50 is formed in a polygonal shape such as a convex polygon or a concave polygon in plan view.

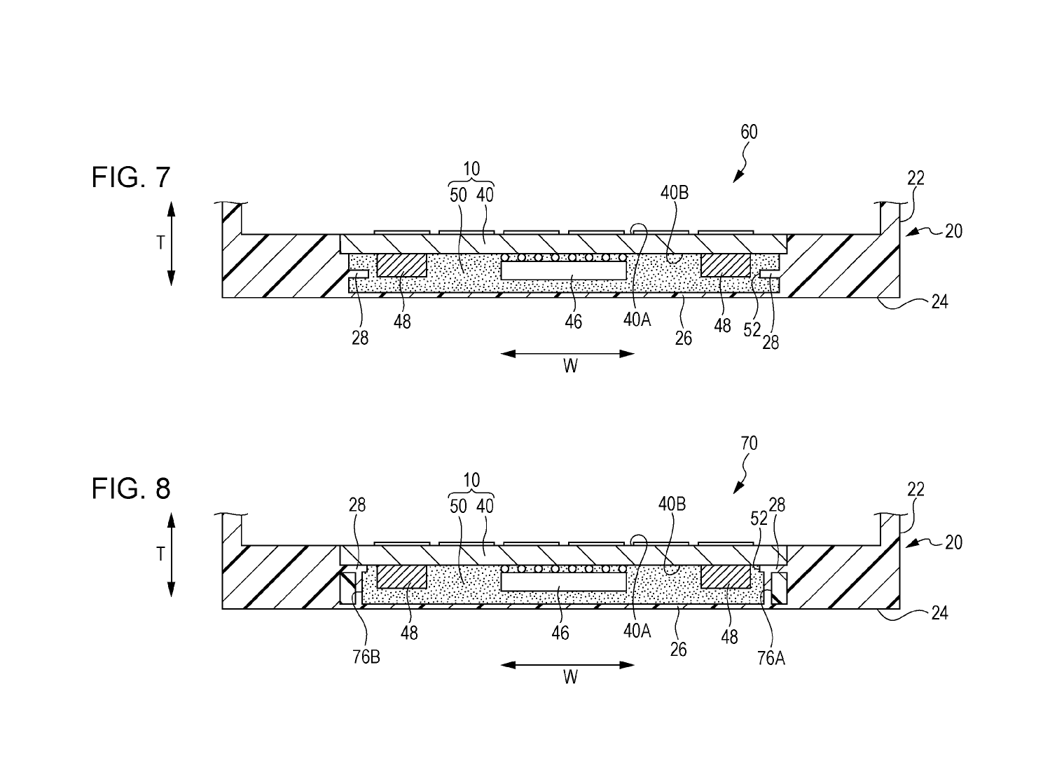

While in the first embodiment the opening 52 is formed in the surface portion on the substrate 40 side of the sealing resin 50, as illustrated as FIG. 7, the opening 52 may be formed in the middle portion (the portion between the surface portion on the substrate 40 side and the surface portion opposite to the substrate 40 side) in the thickness direction (direction T) of the sealing resin 50. When the opening 52 is formed in this way as well, the inflow portion 28 and the coating portion 26 go round both sides in the thickness direction of the sealing resin 50, thereby making it possible to reduce detachment of the coating portion 26 from the sealing resin 50.

### Second Embodiment

Next, a second embodiment will be described.

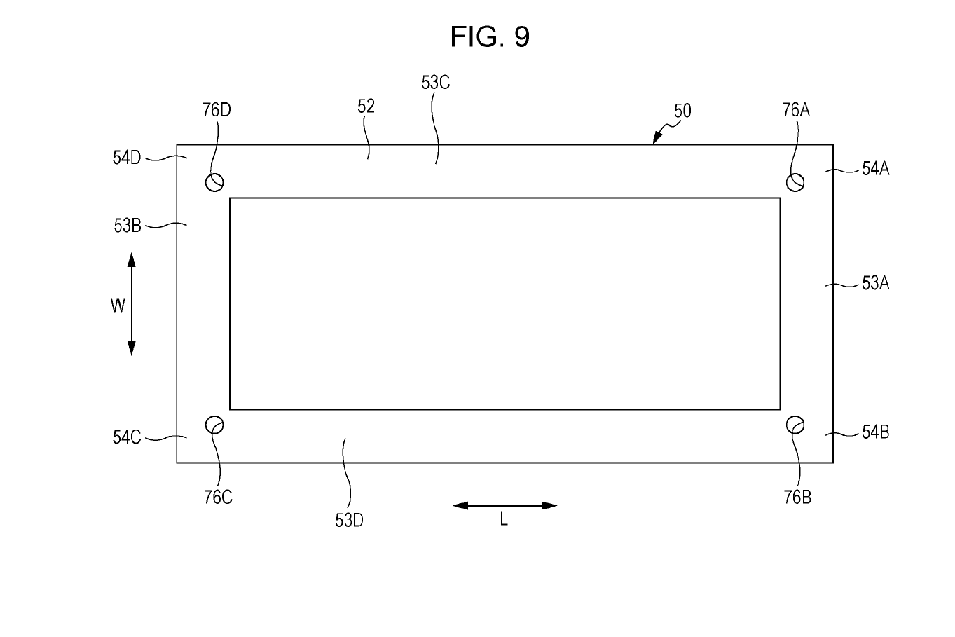

In an electronic apparatus 70 according to the second embodiment illustrated as FIGS. 8 and 9, as opposed to the electronic apparatus 60 (see FIGS. 1 to 3) according to the first embodiment mentioned above, the configuration of the sealing resin 50 is changed as described below.

That is, in the second embodiment, a plurality of communication passages 76A to 76D are formed in the sealing resin 50. Each of the plurality of communication passages 76A to 76D is formed as a hole that extends in the thickness direction (direction T) of the sealing resin 50, and provides communication between the outside of the sealing resin 50 and the opening 52. In addition, as illustrated as FIG. 9, the plurality of communication passages 76A to 76D are formed at corner portions 54A to 54D, respectively, of the sealing resin 50.

A manufacturing method for the electronic apparatus 70 according to the second embodiment is the same as the manufacturing method for the electronic apparatus 60 according to the first embodiment mentioned above. At the time of molding of the housing 20 made of resin, a part of molten resin flows into the opening 52, and the inflow portion 28 is formed (see FIG. 8). The plurality of communication passages 76A to 76D may be formed at the time of molding of the sealing resin 50, or may be formed by additional machining after molding of the sealing resin 50.

When the plurality of communication passages 76A to 76D are formed in the sealing resin 50 in this way, in a case where a part of molten resin flows into the opening 52 at the time of molding of the housing 20 made of resin, the air inside the opening 52 may be discharged to the outside via the communication passages 76A to 76D. Moreover, it is also possible to make a part of molten resin flow into the opening 52 via the communication passages 76A to 76D. Consequently, the inflow portion 28 may be formed smoothly.

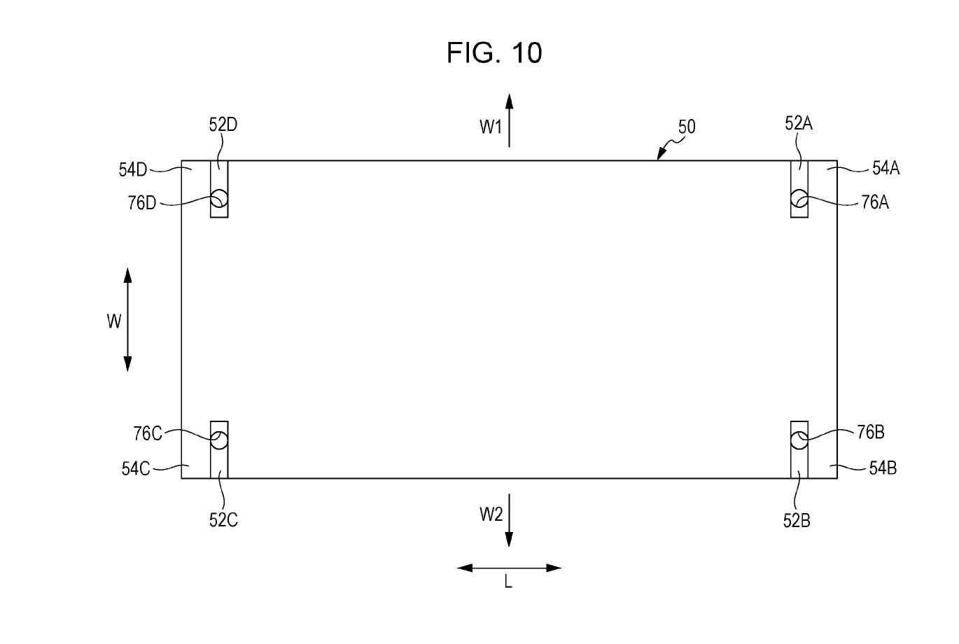

In the second embodiment, as illustrated as FIG. 10, a plurality of openings 52A to 52D may be formed in the sealing resin 50. In this case, the plurality of openings 52A to 52D may be formed at corner portions 54A to 54D, respectively, of the sealing resin 50. The plurality of openings 52A to 52D may be formed at the time of molding of the sealing resin 50, or may be formed by additional machining after molding of the sealing resin 50.

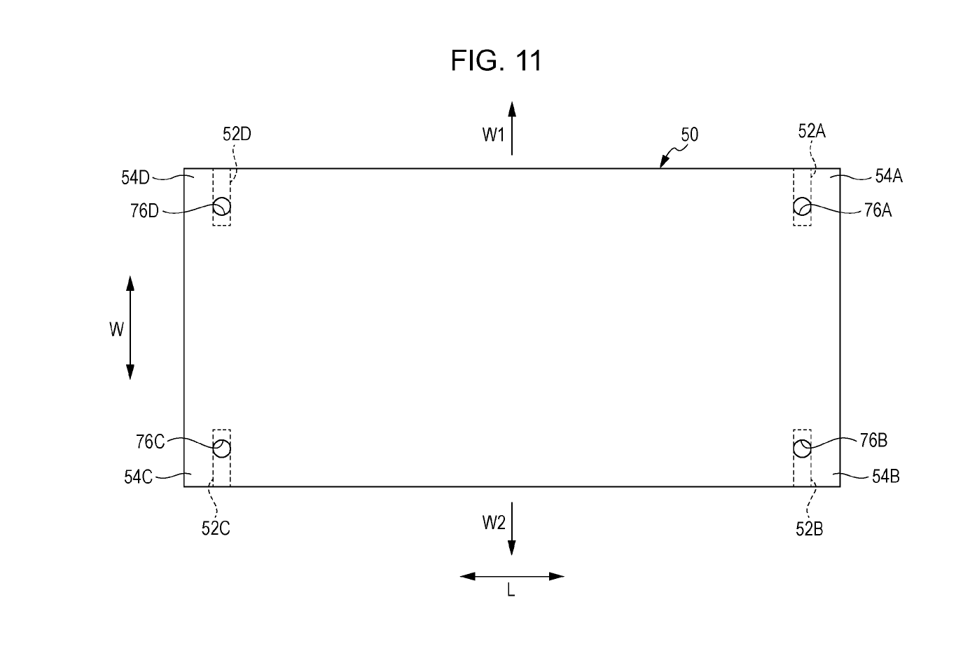

Further, as illustrated as FIG. 10, each of the plurality of openings 52A to 52D may be formed as a groove that is open in a surface on one side in the thickness direction of the sealing resin 50 (surface on the substrate 40 side illustrated as FIG. 8), and extends in the transverse direction of the sealing resin 50. Moreover, as illustrated as FIG. 11, each of the plurality of openings 52A to 52D may be formed as a hole that extends in the transverse direction of the sealing resin 50. In the modifications illustrated as FIGS. 10 and 11, one end of each of the openings 52A and 52D is open on one side (W1 side) in the transverse direction of the sealing resin 50, and the other end of each of the openings 52A and 52D is terminated. One end of each of the openings 52B and 52C is open on the other side (W2 side) in the transverse direction of the sealing resin 50, and the other end of each of the openings 52B and 52C is terminated.

When each of the plurality of openings 52A to 52D is formed as a groove or a hole in this way as well, the inflow portion 28 and the coating portion 26 are formed so as to go round both sides in the thickness direction of the sealing resin 50 (see FIG. 8). Therefore, detachment of the coating portion 26 from the sealing resin 50 may be reduced even in a case where, for example, bending stress is exerted on the housing 20, or impact caused by dropping is applied to the housing 20.

Moreover, when each of the plurality of openings 52A to 52D is formed as a groove or a hole (in a shape with a narrow transverse width), the space for forming the plurality of openings 52A to 52D may be reduced, thereby increasing the freedom of layout of the plurality of openings 52A to 52D.

The openings 52A and 52D and the openings 52B and 52C are separated from each other in the transverse direction of the sealing resin 50. In addition, the openings 52A and 52B and the openings 52C and 52D are separated from each other in the longitudinal direction of the sealing resin 50. Therefore, the coating portion 26 is restrained in the longitudinal direction and the transverse direction by the inflow portion 28 that has flown into each of the cutout portions 53A to 53D, which also makes it possible to reduce detachment of the coating portion 26 from the sealing resin 50.

While in the modifications illustrated as FIGS. 10 and 11 the plurality of openings 52A to 52D extend in the transverse direction of the sealing resin 50 and are open in the transverse direction of the sealing resin 50, the plurality of openings 52A to 52D may extend in the longitudinal direction of the sealing resin 50 and be open in the longitudinal direction of the sealing resin 50.

### Third Embodiment

Next, a third embodiment will be described.

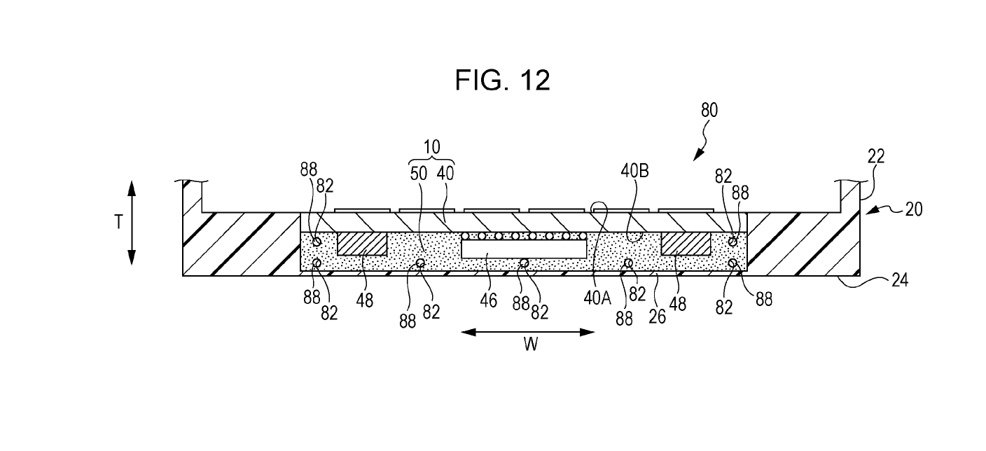

In an electronic apparatus 80 according to the third embodiment illustrated as FIG. 12, as opposed to the electronic apparatus 60 (see FIGS. 1 to 3) according to the first embodiment mentioned above, the configuration of the sealing resin 50 is changed as described below.

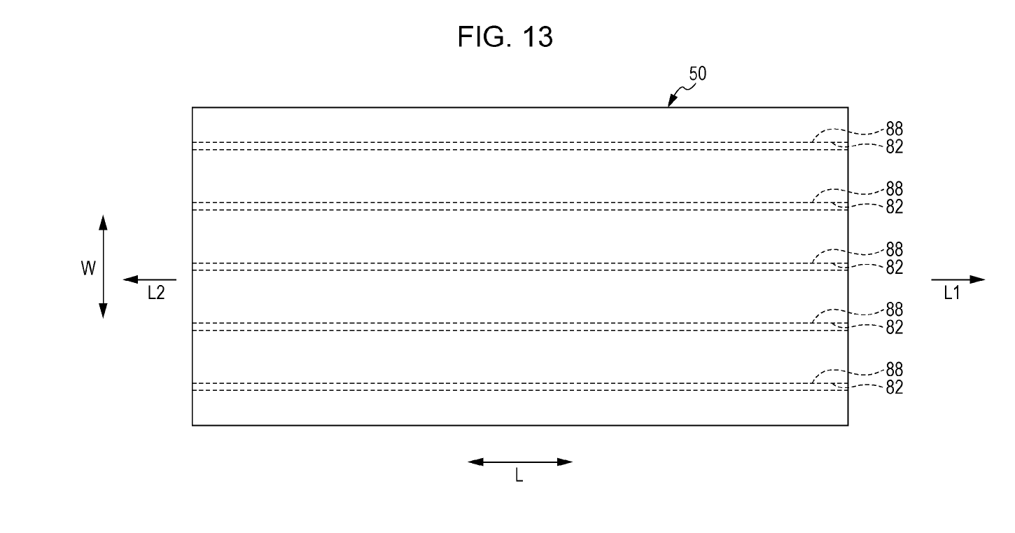

That is, in the third embodiment, a plurality of openings 82 are formed in the sealing resin 50. Each of the plurality of openings 82 is formed as a narrow hole with a circular cross section. As illustrated as FIG. 13, each of the openings 82 passes through the sealing resin 50 in the longitudinal direction (direction L) of the sealing resin 50. That is, one end of each of the openings 82 is open on one side (L1 side) in the longitudinal direction of the sealing resin 50, and the other end of each of the openings 82 is open on the other side (L2 side) in the longitudinal direction of the sealing resin 50. In addition, the plurality of openings 82 are arranged side by side in the transverse direction (direction W) of the sealing resin 50 (separated from each other in the transverse direction of the sealing resin 50).

A manufacturing method for the electronic apparatus 80 according to the third embodiment is the same as the manufacturing method for the electronic apparatus 60 according to the first embodiment mentioned above. At the time of molding of the housing 20 made of resin, a part of molten resin flows into each of the openings 82, and an inflow portion 88 is formed. The plurality of openings 82 may be formed at the time of molding of the sealing resin 50, or may be formed by additional machining after molding of the sealing resin 50.

When each of the plurality of openings 82 is formed as a through hole in this way as well, the inflow portion 88 and the coating portion 26 are formed so as to go round both sides in the thickness direction (direction T) of the sealing resin 50. Therefore, detachment of the coating portion 26 from the sealing resin 50 may be reduced even in a case where, for example, bending stress is exerted on the housing 20, or impact caused by dropping is applied to the housing 20.

Moreover, when the plurality of openings 82 pass through the sealing resin 50 in the longitudinal direction of the sealing resin 50 in this way, it is possible to secure the size (length) of the inflow portion 88. This makes it possible to reduce detachment of the coating portion 26 from the sealing resin 50 more effectively.

The plurality of openings 82 are separated from each other in the transverse direction of the sealing resin 50. Therefore, the coating portion 26 is restrained in the transverse direction by the inflow portion 88 that has flown into each of the openings 82, which also makes it possible to reduce detachment of the coating portion 26 from the sealing resin 50.

When the plurality of openings 82 pass through the sealing resin 50 in the longitudinal direction of the sealing resin 50, in a case where a part of molten resin flows into the openings 82 from one side of the openings 82 at the time of molding of the housing 20 made of resin, the air inside the openings 82 may be discharged to the outside from the other side of the openings 82. Consequently, the inflow portion 88 may be formed smoothly.

Each of the plurality of openings 82 is formed as a narrow hole with a circular cross section. Therefore, the space for forming the plurality of openings 82 may be reduced, thereby increasing the freedom of layout of the plurality of openings 82.

While the plurality of openings 82 extend in the longitudinal direction of the sealing resin 50 and are open in the longitudinal direction of the sealing resin 50, the plurality of openings 82 may extend in the transverse direction of the sealing resin 50 and be open in the transverse direction of the sealing resin 50.

### Fourth Embodiment

Next, a fourth embodiment will be described.

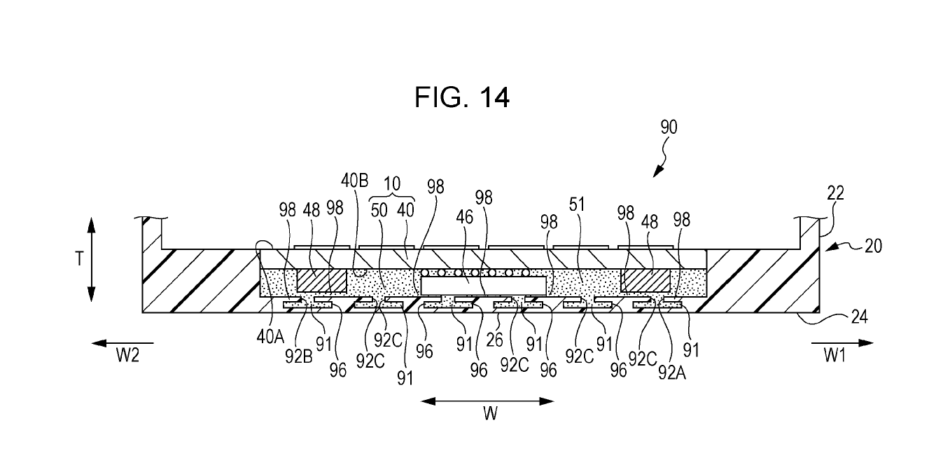

In an electronic apparatus 90 according to the fourth embodiment illustrated as FIG. 14, as opposed to the electronic apparatus 60 (see FIGS. 1 to 3) according to the first embodiment mentioned above, the configuration of the sealing resin 50 is changed as described below.

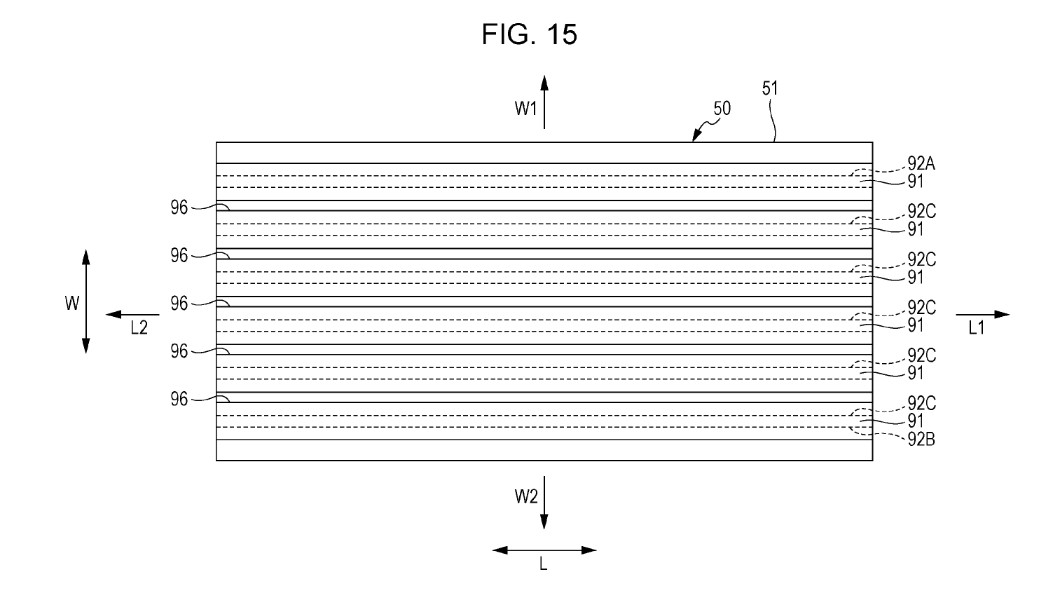

That is, in the fourth embodiment, a plurality of protrusions 91 are formed in the sealing resin 50. The protrusions 91 have a T-shaped cross section when the sealing resin 50 is viewed along the longitudinal direction. The protrusions 91 are extended to the side of the sealing resin 50 opposite to the substrate 40 from a plate-like main body portion 51. As illustrated as FIG. 15, the plurality of protrusions 91 extend along the longitudinal direction (direction L) of the sealing resin 50, and are arranged side by side in the transverse direction (direction W) of the sealing resin 50.

As the plurality of protrusions 91 are formed in the sealing resin 50, a plurality of openings 92A to 92C are formed in the sealing resin 50 as illustrated as FIGS. 14 and 15. The plurality of openings 92A to 92C are divided from each other by the proximal end portions of the plurality of protrusions 91. The plurality of openings 92A to 92C are arranged side by side in the transverse direction of the sealing resin 50 (separated from each other in the transverse direction of the sealing resin 50).

Of the plurality of openings 92A to 92C, each of the openings 92A and 92B on both end sides is formed as a cutout that is open in the transverse direction (direction W) of the sealing resin 50. That is, the opening 92A is open on one side (W1 side) in the transverse direction of the sealing resin 50, and the other opening 92B is open on the other side (W2 side) in the transverse direction of the sealing resin 50. The openings 92A and 92B on both end sides are formed over the entire longitudinal direction of the sealing resin 50.

Each of the plurality of openings 92C located inside the openings 92A and 92B on both end sides is formed as a hole with a flat, rectangular cross section. As illustrated as FIG. 15, all of the plurality of openings 92C pass through the sealing resin 50 in the longitudinal direction (direction L) of the sealing resin 50. That is, one end of each of the openings 92C is open on one side (L1 side) in the longitudinal direction of the sealing resin 50, and the other end of each of the openings 92C is open on the other side (L2 side) in the longitudinal direction of the sealing resin 50.

The above-mentioned plurality of protrusions 91 with a T-shaped cross section are formed at a distance from each other in the transverse direction of the sealing resin 50. A plurality of communication passage 96 are each formed between the distal end portions of the plurality of protrusions 91. Each of the communication passages 96 pass through the sealing resin 50 in the thickness direction (direction T) of the sealing resin 50, and provides communication between the outside of the sealing resin 50 and each of the openings 92C. In addition, as illustrated as FIG. 15, each of the communication passages 96 is formed in the shape of a groove that extends in the longitudinal direction of the sealing resin 50. The plurality of openings 92A to 92C and the communication passages 96 are formed by, for example, using a comb-like insert or the like having a shape corresponding to each of the plurality of openings 92A to 92C and the communication passages 96, at the time of molding of the sealing resin 50 using a mold.

A manufacturing method for the electronic apparatus 90 according to the fourth embodiment is the same as the manufacturing method for the electronic apparatus 60 according to the first embodiment mentioned above. At the time of molding of the housing 20 made of resin, a part of molten resin flows into each of the openings 92A to 92C, and an inflow portion 98 is formed. Other than being formed at the time of molding of the sealing resin 50, the plurality of communication passages 96 may be formed by additional machining after molding of the sealing resin 50.

In this way, according to the fourth embodiment, the plurality of openings 92A to 92C that are open in the longitudinal direction and transverse direction of the sealing resin 50 are formed in the sealing resin 50. The inflow portion 98 is made to flow into each of the plurality of openings 92A to 92C. Therefore, because the inflow portion 98 and the coating portion 26 go round both sides in the thickness direction (direction T) of the sealing resin 50, detachment of the coating portion 26 from the sealing resin 50 may be reduced even in a case where, for example, bending stress is exerted on the housing 20, or impact caused by dropping is applied to the housing 20.

The plurality of openings 92A to 92C are separated from each other in the transverse direction of the sealing resin 50. Therefore, the coating portion 26 is restrained in the transverse direction by the inflow portion 98 that has flown into each of the openings 92A to 92C, which also makes it possible to reduce detachment of the coating portion 26 from the sealing resin 50.

The plurality of communication passages 96 are formed in the sealing resin 50. Therefore, in a case where a part of molten resin flows into the openings 92C at the time of molding of the housing 20 made of resin, the air inside the openings 92C may be discharged to the outside via the communication passages 96. Moreover, it is also possible to make a part of molten resin flow into the openings 92C via the communication passages 96. Consequently, the inflow portion 98 may be formed smoothly.

The plurality of openings 92C pass through the sealing resin 50 in the longitudinal direction of the sealing resin 50. Accordingly, in a case where a part of molten resin flows into the openings 92C from one side of the openings 92C at the time of molding of the housing 20 made of resin, the air inside the openings 92C may be discharged to the outside from the other side of the openings 92C. This also makes it possible to form the inflow portion 98 smoothly.

The openings 92A and 92B are formed over the entire longitudinal direction of the sealing resin 50, and the plurality of openings 92C are formed so as to pass through the sealing resin 50 in the longitudinal direction of the sealing resin 50. Therefore, it is possible to secure the size (length) of the inflow portion 98, which makes it possible to reduce detachment of the coating portion 26 from the sealing resin 50 more effectively.

Each of the plurality of openings 92C on the central side is formed as a hole with a flat, rectangular cross section (in a shape with a small dimension in the thickness direction of the sealing resin 50), the space for forming the plurality of openings 92C may be reduced. This makes it possible to increase the freedom of layout of the plurality of openings 92C.

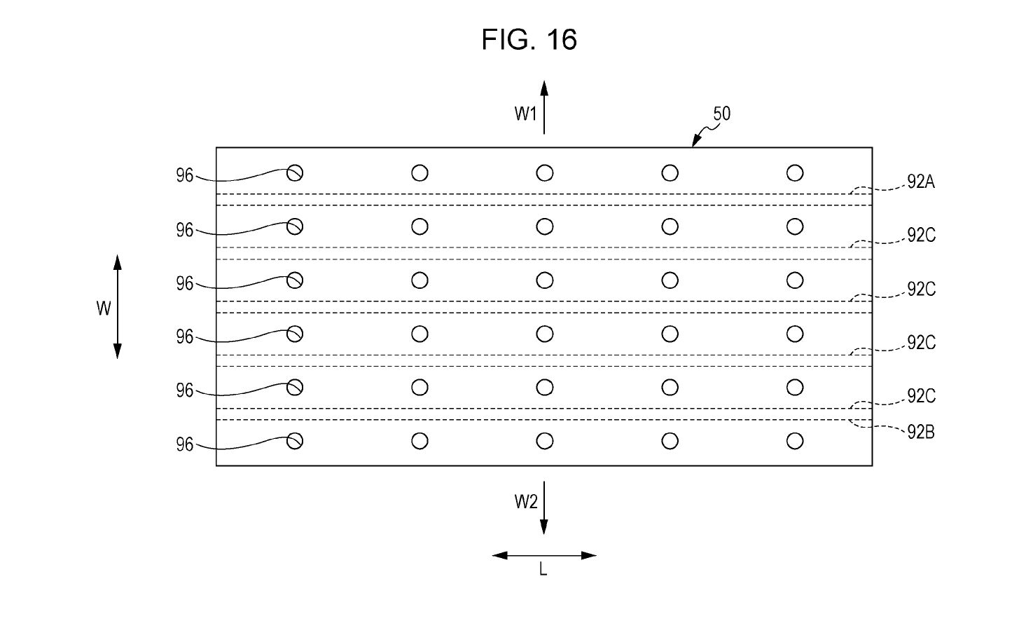

While the plurality of communication passages 96 are formed in the shape of a groove that extends in the longitudinal direction of the sealing resin 50, the plurality of communication passages 96 may be formed in the shape of a hole that passes through the sealing resin 50 in the thickness direction of the sealing resin 50 as illustrated as FIG. 16.

While the plurality of openings 92A to 92C extend in the longitudinal direction of the sealing resin 50, the plurality of openings 92A to 92C may extend in the transverse direction of the sealing resin 50. Reference Example

Next, a reference example will be described.

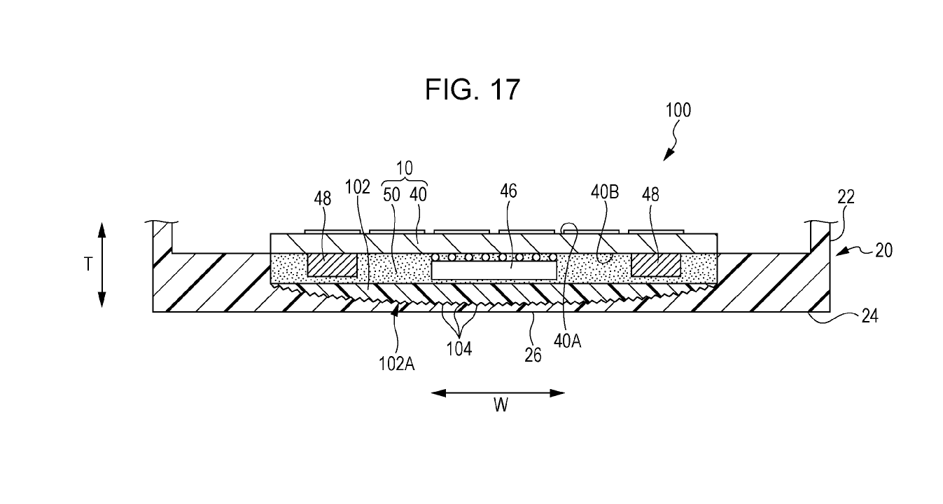

The configuration of an electronic apparatus 100 according to the reference example illustrated as FIG. 17 is changed as described below, as opposed to the electronic apparatus 60 (see FIGS. 1 to 3) according to the first embodiment mentioned above.

That is, in the reference example, the electronic component 46 as an IC is arranged in the central portion of the sealing resin 50. In addition, a sheet member 102 is provided in an overlapping manner on the side of the sealing resin 50 opposite to the substrate 40. The sheet member 102 is formed of, for example, a material having elasticity such as a mixture of nitrile rubber and phenolic resin.

The sheet member 102 is formed so as to become thicker toward the central portion of the sealing resin 50 (the central portion of the electronic component 46 in plan view). The surface of the sheet member 102 opposite to the substrate 40 is formed as a convex surface 102A that is convex to the side opposite to the substrate 40. A plurality of minute protrusions 104 (for example, protrusions with a triangular cross section) are formed over the entire convex surface 102A. The protrusions 104 are formed by laser machining, shot blasting, or the like.

A manufacturing method for the electronic apparatus 100 according to the reference example is the same as the manufacturing method for the electronic apparatus 60 according to the first embodiment mentioned above. The housing 20 made of resin is formed integrally with the substrate module 10 and the sealing resin 50 by molding. The coating portion 26 is formed opposite to the sealing resin 50 across the sheet member 102.

According to the reference example, even in a case where a bending load or impact load is applied to the housing 20, and this load is exerted on the central portion of the back portion 24, this load may be absorbed by the sheet member 102. The load not fully absorbed by the sheet member 102 is transmitted to the outer peripheral side of the sealing resin 50 through the electronic component 46 as an PC that is rigid. However, because most of the load exerted on the central portion of the back portion 24 is absorbed by the sheet member 102, concentration of stress on the peripheral edge portion of the coating portion 26 may be reduced. In this way, it is possible to reduce detachment of the coating portion 26 from the sealing resin 50.

The plurality of minute protrusions 104 are formed in the convex surface 102A on the side (the coating portion 26 side) of the sheet member 102 opposite to the substrate 40. Therefore, the surface area of the convex surface 102A may be increased by the plurality of minute protrusions 104. Consequently, the adhesion between the sheet member 102 and the coating portion 26 may be ensured and, therefore, detachment of the coating portion 26 may be reduced more effectively.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A substrate module comprising:
a substrate on which an electronic component is mounted; and
a sealing resin that seals the electronic component, and has an opening, the opening being open along an extending direction of the substrate.

2. The substrate module according to claim 1, wherein the opening is formed in an annular shape along a peripheral edge portion of the sealing resin.

3. The substrate module according to claim 1, wherein:
the sealing resin is formed in a polygonal shape in plan view; and
the opening is formed at a corner portion of the sealing resin.

4. The substrate module according to claim 1, wherein:
the sealing resin is formed in a polygonal shape in plan view; and
the opening is formed along a side portion of the sealing resin.

5. The substrate module according to claim 1, wherein the opening is a cutout.

6. The substrate module according to claim 1, wherein the opening is a groove or a hole.

7. The substrate module according to claim 1, wherein the opening passes through the sealing resin along the extending direction of the substrate.

8. The substrate module according to claim 1, wherein the sealing resin has a communication passage that provides communication between an outside of the sealing resin and the opening.

9. The substrate module according to claim 8, wherein:
the sealing resin is formed in a polygonal shape in plan view; and
the communication passage is formed at a corner portion of the sealing resin.

10. The substrate module according to claim 1, wherein:
the sealing resin has a plurality of the openings; and
the plurality of openings are separated from each other along the extending direction of the substrate.

11. An electronic apparatus comprising:
the substrate module according to claim 1; and
a housing that is formed by molding, the housing integrally having
a coating portion that is formed opposite to the substrate across the sealing resin, and
an inflow portion that has flown into the opening.

12. The electronic apparatus according to claim 11, wherein the inflow portion and the coating portion go round both sides in a thickness direction of the sealing resin.

13. The electronic apparatus according to claim 11, further comprising a liquid crystal display, wherein:
the housing has a back portion, the back portion being provided opposite to the liquid crystal display with respect to the substrate; and
the coating portion is formed in the back portion.

14. The electronic apparatus according to claim 11, wherein the coating portion is formed so as to be smaller than each of the substrate and the sealing resin.

15. The electronic apparatus according to claim 11, wherein the housing is made of polypropylene.

16. An electronic apparatus comprising:
a substrate on which an electronic component is mounted;
a sealing resin that seals the electronic component;
a sheet member that is provided in an overlapping manner on a side of the sealing resin opposite to the substrate, the sheet member being formed so as to become thicker toward a central portion of the electronic component in plan view, the sheet member having a convex surface on a side of the sheet member opposite to the substrate;
a plurality of protrusions that are formed in the convex surface; and
a housing that is formed by molding, and has a coating portion, the coating portion being formed opposite to the sealing resin across the sheet member.

17. A manufacturing method for an electronic component, comprising:
sealing an electronic component mounted on a substrate with a sealing resin, and forming an opening in the sealing resin, the opening being open along an extending direction of the substrate; and
forming a housing by molding, the housing integrally having
a coating portion that is formed opposite to the substrate across the sealing resin, and
an inflow portion that has flown into the opening.
